(19) United States
(12) Patent Application Publication
(10) Pub. No.: US 2024/0387429 A1
(43) Pub. Date: Nov. 21, 2024

(54) INTEGRATED CIRCUIT (IC) CHIP WITH BUMP INTERCONNECTS EACH HAVING MULTIPLE CONTACT AREAS, RELATED IC PACKAGES, AND METHODS OF FABRICATION

(71) Applicant: QUALCOMM Incorporated, San Diego, CA (US)

(72) Inventors: Yujen Chen, Taichung (TW); Yangyang Sun, San Diego, CA (US); Wei Wang, San Diego, CA (US)

(21) Appl. No.: 18/318,691

(22) Filed: May 16, 2023

(51) Int. Cl. H01L 23/00

(52) U.S. Cl. CPC H01L 24/13; H01L 24/05; H01L 2224/02125; H01L 2224/0215; H01L 2224/03011; H01L 2224/05557; H01L 2224/13082

(57) ABSTRACT

Underfill and bump interconnects in a circuit package expand at different rates during a thermal reflow process, causing stress at one end of a bump interconnect that couples to a metal pad. A bump interconnect having multiple isolated areas of contact between a conductive pillar and the metal pad, rather than a single larger continuous contact area, distributes the concentration of stresses to reduce the peak stress, which reduces the chances of damage due to stress occurring between the metal pad and the conductive pillar or in a dielectric layer adjacent to the metal pad. In some examples, before formation of the conductive pillar, a passivation layer is disposed in a pattern on the metal pad with openings in which a plurality of surfaces of the second end of the conductive pillar contact the metal pad.

### BACKGROUND

### I. Field of the Disclosure

The technology of the disclosure relates generally to integrated circuit (IC) packaging and, more particularly, to interconnecting an IC to an IC package.

### II. Background

Electronic devices, such as cell phones, laptops, and tablets, contain integrated circuit (IC) packages, including one or more IC chips. IC chips may include analog circuits, digital logic circuits, and/or memory circuits on a semiconductor substrate. Substrates may also contain interconnects for interconnecting IC chips and other components in an IC package and may also couple an IC package to other packages, external memories, power sources, media ports, and/or input/output devices to transmit and/or receive clock signals, control signals, data signals, and/or power supply voltage signals. IC chips may be mounted in a circuit package in a flip-chip configuration, in which an array of bump interconnects on a first side of a first substrate is coupled to circuits on a second side of the first substrate. A second substrate includes an array of contact pads that are disposed in an arrangement corresponding to the array of bump interconnects on the IC chip. To form an IC package, the array of bump interconnects and contact pads are aligned and placed in contact with each other. Each bump interconnect includes a conductive pillar with a solder on one end to couple the conductive pillar to a corresponding contact pad. The space between the opposing faces and around the bump interconnects is filled with an underfill material. The IC package is heated in a thermal reflow process, allowing the solder to melt and couple to the contact pad. As the IC package is heated, the semiconductor substrate, the bump interconnects, and the underfill material all expand. However, because different materials expand at different rates, based on their respective coefficients of thermal expansion (CTE), stresses are created that can cause package defects.

### SUMMARY

Aspects disclosed in the detailed description include integrated circuit chips with bump interconnects, each having multiple contact areas. Related methods of fabricating circuit packages are also disclosed. The IC chip includes an array of bump interconnects for coupling a first side of a first substrate, such as a semiconductor substrate with integrated circuits (ICs) on a second side to a second substrate. One end of each of the bump interconnects of the IC chip is coupled to a metal pad on the first side of the first substrate, while the other end of each bump interconnect is configured to physically and electrically couple the IC chip to the second substrate (e.g., another IC chip, interposer, or circuit board) to form a circuit package. In this regard, each bump interconnect includes a conductive pillar having a solder on a first end configured to be coupled to a contact pad on the second substrate and a second end coupled to the metal pad on the first substrate of the IC chip, to couple the IC chip to the second substrate. In a thermal reflow process used to bond the solder to the contact pads of the second substrate, stresses can be created by an underfill material disposed between the first substrate of the IC chip and the second substrate expanding at a different rate than the bump interconnects. Such stresses can cause damage to the contact between the bump interconnect and the metal pad and/or to a dielectric layer adjacent to the metal pad. In a bump interconnect where the conductive pillar has a large single continuous contact area with the metal pad, the peak stress occurs at the center of the continuous contact area where the stresses are most concentrated. Employing multiple contact areas instead of a single larger continuous contact area distributes the stress to reduce or avoid damage.

In exemplary aspects, to reduce or avoid damage caused by stress between the conductive pillars of the bump interconnects and the metal pads on the first substrate of the IC chip, the conductive pillar in each of the bump interconnects includes a plurality of surfaces that provide a plurality of contact areas at which the conductive pillars contact the metal pads of the first substrate in the IC chip. Having multiple smaller surfaces over which the contact stress is distributed rather than a single larger continuous end surface with a higher concentration of stresses in one contact area reduces the chance of damage due to such stresses. Also, since multiple contact areas for each bump interconnect provide parallel contact between the conductive pillar and the metal pad of the first substrate, the areas of the contact areas are combined to avoid a resistance increase between the conductive pillar and the metal pad.

In other exemplary aspects, a passivation layer may be disposed on the metal pad with a pattern of multiple openings to facilitate providing multiple contact areas at which surfaces of the bump interconnects contact the metal pads of the first substrate. For example, the passivation layer can be formed before the formation of the conductive pillar of the bump interconnects. The second end of the conductive pillar of each bump interconnect contacts the metal pad of the first substrate through the multiple openings provided in the passivation layer to provide multiple contact areas between the bump interconnect contacts and the metal pad to distribute the contact stress and reduce the chance of defects.

In this regard, in one aspect, an IC chip is disclosed. The IC chip includes a plurality of bump interconnects on a first side of a first substrate and a plurality of circuit devices on a second side of the first substrate. The plurality of bump interconnects is electrically coupled to the at least one circuit device among the plurality of circuit devices. Each bump interconnect of the plurality of bump interconnects comprises a metal pad, a conductive pillar comprising a first end and a second end opposite to the first end in a first direction, a solder on the first end of the conductive pillar, and the second end of the conductive pillar comprises a plurality of surfaces in contact with the metal pad in respective contact areas.

In another aspect, a method of fabricating an IC is disclosed. The method includes forming a plurality of circuit devices on a second side of a first substrate and a plurality of bump interconnects on a first side of the first substrate. The plurality of bump interconnects is electrically coupled to the at least one circuit device among the plurality of circuit devices. Each bump interconnect of the plurality of bump interconnects comprises a metal pad, a conductive pillar comprising a first end and a second end opposite to the first end in a first direction, a solder on the first end of the conductive pillar, and the second end of the conductive pillar comprises a plurality of surfaces in contact with the metal pad in respective contact areas.

In another aspect, an IC package is disclosed. The IC package includes a first substrate and a plurality of bump interconnects on a first side of the first substrate. Each bump interconnect comprises a metal pad, a conductive pillar comprising a first end and a second end opposite to the first end in a first direction, a solder on the first end of the conductive pillar, and a plurality of surfaces at the second end of the conductive pillar in contact with the metal pad in a plurality of respective contact areas. The IC package further includes a second substrate comprising a plurality of contact pads, each coupled to the solder of a corresponding one of the plurality of bump interconnects. The first substrate includes a plurality of circuit devices on a second side of the first substrate opposite to the first end in a first direction, and the plurality of bump interconnects electrically coupled to at least one of the plurality of circuit devices and to the second substrate.

### BRIEF DESCRIPTION OF THE DRAWINGS

FIG. 1 is a perspective view of an exemplary integrated circuit (IC) chip, including bump interconnects on a first substrate, wherein each bump interconnect includes a respective conductive pillar having multiple surfaces providing contact areas at which the conductive pillar contacts a metal pad on a first substrate with reduced contact stresses;

FIG. 2 is a cross-sectional side view of an exemplary IC package, including the IC chip of FIG. 1, coupled to a second substrate by the plurality of bump interconnects, each having multiple contact areas for reduced contact stress;

FIG. 3A is a cross-sectional side view of an exemplary bump interconnect having a plurality of contact areas at which the end surfaces of a conductive pillar are in contact with the metal pad;

FIG. 3B is a cross-sectional end view of the exemplary bump interconnect shown in FIG. 3A;

FIG. 4A is a cross-sectional side view of a conventional bump interconnect having a single contact area with higher contact stress provided for comparison to FIG. 3A;

FIG. 4B is a cross-sectional end view of a conventional bump interconnect provided for comparison to FIG. 3B;

FIG. 5A is a cross-sectional end view of the conventional bump interconnect of FIGS. 4A and 4B;

FIG. 5B is an inverted cross-sectional side view of the conductive pillar of the bump interconnect of FIGS. 4A and 4B;

FIG. 6A is a cross-sectional end view of the exemplary bump interconnect of FIGS. 3A and 3B with multiple contact areas to maintain a low resistance connection with reduced stress at which a conductive pillar contacts a metal pad on a semiconductor substrate;

FIG. 6B is an inverted cross-sectional side view of the conductive pillar of the bump interconnects of FIGS. 3A, 3B, and 6A in contact with a semiconductor substrate;

FIG. 7 is a flowchart illustrating an exemplary fabrication process for fabricating a bump interconnect in which an end of a conductive pillar includes a plurality of surfaces coupled to a metal pad to reduce stress between the conductive pillar and the metal pad, including but not limited to the bump interconnects in FIGS. 3A, 3B, 6A, 6B and 10-12;

FIGS. 8A-8C illustrate another exemplary fabrication process, as illustrated in FIGS. 9A-9C, of fabricating bump interconnects in which an end of a conductive pillar includes a plurality of surfaces coupled to a metal pad to reduce stress between the conductive pillar and the metal pad, including the bump interconnects in FIGS. 3A, 3B, 6A, 6B, and 10-12;

FIGS. 9A-9C are a flowchart illustrating exemplary stages of fabrication of the bump interconnects in FIGS. 3A, 3B, 6A, 6B, and 10-12 in which an end of a conductive pillar includes a plurality of surfaces coupled to a metal pad to provide multiple contact areas having reduced stresses between the conductive pillar and the metal pad, as illustrated in FIGS. 8A-8C;

FIGS. 10-12 are cross-sectional bottom views of other examples of the bump interconnects in which the end surfaces of a conductive pillar include a plurality of contact areas in contact with a metal pad to reduce stress between the conductive pillar and the metal pad without increasing resistance;

FIG. 13 illustrates an exemplary wireless communications device that includes radio frequency (RF) components formed from one or more IC chips wherein the IC chips can include bump interconnects in which isolated end surfaces of a conductive pillar provide a plurality of contact areas with a metal pad to reduce stress between the conductive pillar and the metal pad, including but not limited to the bump interconnects in FIGS. 3A and 3B, and according to, but not limited to, any of the exemplary fabrication processes in FIGS. 7 and 8A-8C; and

FIG. 14 illustrates an example of a processor-based system that can include an IC chip(s) that includes bump interconnects in which the end surfaces of a conductive pillar include a plurality of contact areas coupled to a metal pad to reduce stress between the conductive pillar and the metal pad without increasing resistance, including but not limited to the bump interconnects illustrated in FIGS. 3A, 3B, 6A, 6B, and 10-12 and according to, but not limited to, any of the exemplary fabrication processes in FIGS. 7 and 8A-8C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include integrated circuit chips with bump interconnects, each having multiple contact areas. Related methods of fabricating circuit packages are also disclosed. The IC chip includes an array of bump interconnects for coupling a first side of a first substrate, such as a semiconductor substrate with integrated circuits (ICs) on a second side to a second substrate. One end of each of the bump interconnects of the IC chip is coupled to a metal pad on the first side of the first substrate, while the other end of each bump interconnect is configured to physically and electrically couple the IC chip to the second substrate (e.g., another IC chip, interposer, or circuit board) to form a circuit package. In this regard, each bump interconnect includes a conductive pillar having a solder on a first end configured to be coupled to a contact pad on the second substrate and a second end coupled to the metal pad on the first substrate of the IC chip, to couple the IC chip to the second substrate. In a thermal reflow process used to bond the solder to the contact pads of the second substrate, stresses can be created by an underfill material disposed between the first substrate of the IC chip and the second substrate expanding at a different rate than the bump interconnects. Such stresses can cause damage to the contact between the bump interconnect and the metal pad and/or to a dielectric layer adjacent to the metal pad. In a bump interconnect where the conductive pillar has a large single continuous contact area with the metal pad, the peak stress occurs at the center of the continuous contact area where the stresses are most concentrated. Employing multiple contact areas instead of a single larger continuous contact area distributes the stress to reduce or avoid damage.

In exemplary aspects, to reduce or avoid damage caused by stress between the conductive pillars of the bump interconnects and the metal pads on the first substrate of the IC chip, the conductive pillar in each of the bump interconnects includes a plurality of surfaces that provide a plurality of contact areas at which the conductive pillars contact the metal pads of the first substrate in the IC chip. Having multiple smaller end surfaces over which the contact stress is distributed rather than a single larger continuous end surface with a higher concentration of stresses in one contact area reduces the chance of damage due to such stresses. Also, since multiple contact areas for each bump interconnect provide parallel contact between the conductive pillar and the metal pad of the first substrate, the areas of the contact areas are combined to avoid a resistance increase between the conductive pillar and the metal pad.

In other exemplary aspects, a passivation layer may be disposed on the metal pad with a pattern of multiple openings to facilitate providing multiple contact areas at which surfaces of the bump interconnects contact the metal pads of the first substrate. For example, the passivation layer can be formed before the formation of the conductive pillar of the bump interconnects. The second end of the conductive pillar of each bump interconnect contacts the metal pad of the first substrate through the multiple openings provided in the passivation layer to provide multiple contact areas between the bump interconnect contacts and the metal pad to distribute the contact stress and reduce the chance of defects.

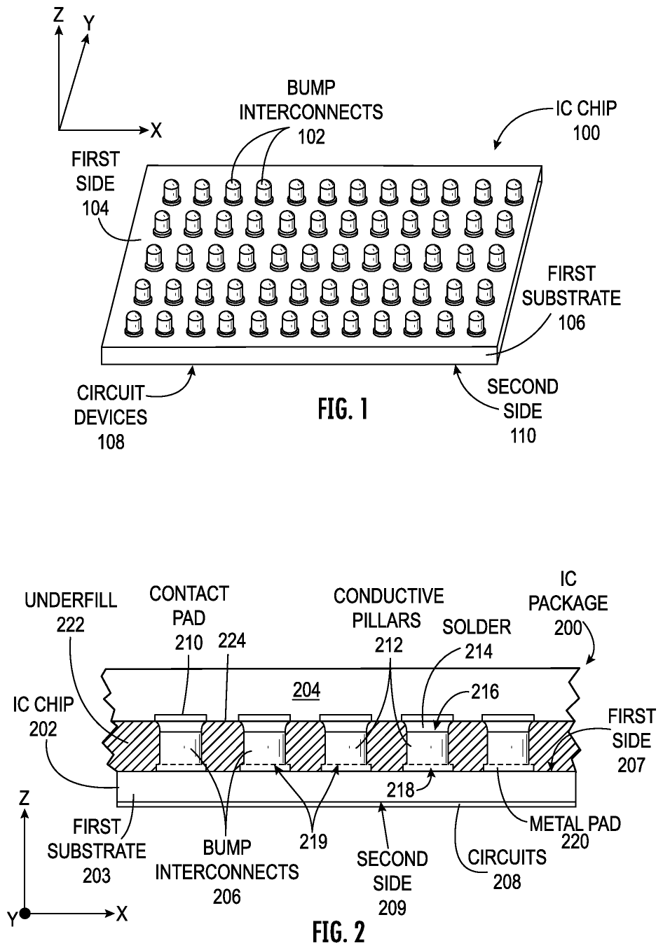

In this regard, FIG. 1 is a perspective view of an integrated circuit (IC) chip 100, including a plurality of bump interconnects 102 on a first side 104 of a first substrate 106 (e.g., a semiconductor substrate) for coupling the IC chip 100 to another substrate of, for example, another IC chip, an interposer, a module, or another element in an IC package (see FIG. 2). Bump interconnects 102 provide an electrical path for electrical signals or power between a plurality of circuit devices 108 on a second side 110 of the IC chip 100 and other circuits in an IC package or external to the IC package. The first substrate 106 may be a silicon substrate or other type of substrate with the plurality of circuit devices 108 comprising transistor circuits or other semiconductor devices in digital logic circuits, analog circuits, and/or memory circuits, for example, on the second side 110 of the first substrate 106.

FIG. 2 is a cross-sectional side view of an IC package 200, including an IC chip 202, which may be the IC chip 100 in FIG. 1, including a first substrate 203 coupled to a second substrate 204. As shown, exemplary bump interconnects 206 on a first side 207 of the first substrate 203 electrically couple circuit devices 208 on a second side 209 of the first substrate 203 to contact pads 210 on the second substrate 204. The bump interconnects 206 are employed to couple the circuit devices 208 to other circuits (not shown) within or external to the IC package 200. The second substrate 204 includes a plurality of contact pads 210 to correspond to the plurality of bump interconnects 206 on the first substrate 203. Each bump interconnect 206 includes a conductive pillar 212 with a solder 214 at a first end 216. The conductive pillar 212 also has a second end 218 coupled to a metal pad 220 on the first side 207 of the first substrate 203. As shown in FIG. 2, the second end 218 includes a plurality of surfaces 219 that are in contact with the metal pad 220. An underfill 222 is disposed in the space around the conductive pillars 212 and between the first side 207 of the first substrate 203 and a third side 224 of the second substrate 204. The surfaces 219 may also be referred to as isolated end surfaces 219, which are isolated or separated from each other by the underfill 222 disposed between them and around them. In some examples, each of the surfaces 219 comprises a flat or planar surface within an area surrounded by the underfill 222 and separated from each other in a direction parallel to the flat or planar surface.

To provide a mechanical and electrical connection of the bump interconnects 206 and the contact pads 210 on the second substrate 204, the IC package 200 is heated to a temperature at which the solder 214 are softened (e.g., molten) in a reflow process. The bump interconnects 206 are positioned in contact with the contact pads 210, and solder of the solder 214 flows onto the contact pads 210.

Also during the reflow process, the underfill 222 is heated and expands but expands at a different rate than the bump interconnects 206 because the underfill 222 and the bump interconnects 206 are formed of different materials having different coefficients of thermal expansion (CTE). The bump interconnects 206 and the underfill 222 between the IC chip 202 and the second substrate 204 each expand laterally (e.g., in the X-axis and Y-axis directions) as well as vertically (e.g., in the Z-axis direction). Stresses are created in contact areas where the isolated end surfaces 219 of the conductive pillars 212 are in contact with the metal pads 220 because of the different rates of expansion of the bump interconnects 206, and the underfill 222.

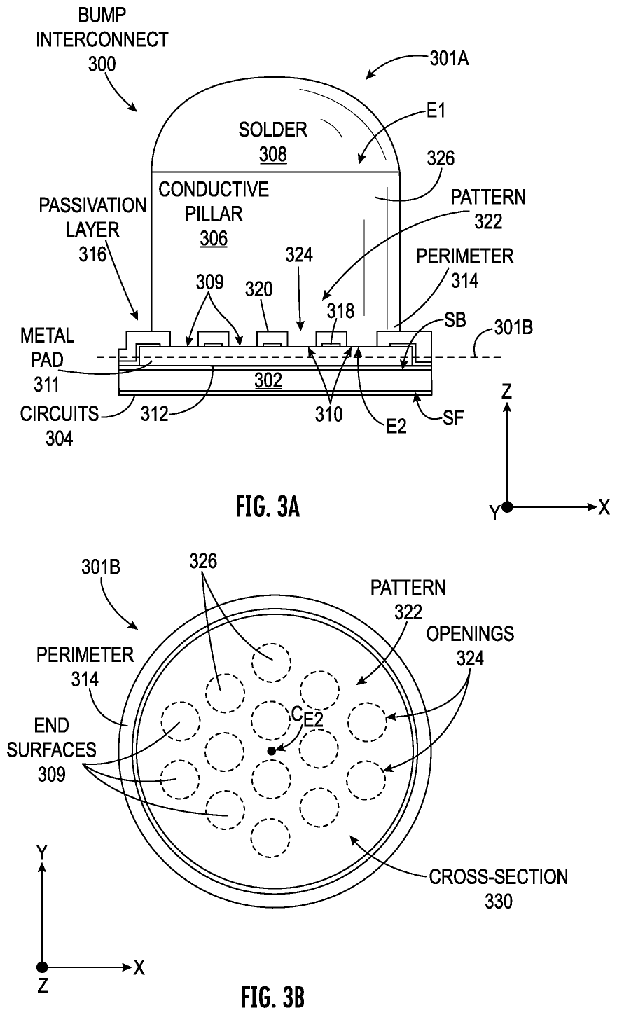

FIG. 3A is a cross-sectional side view 301A of an exemplary bump interconnect 300, which may be the bump interconnects 102 and 206 of FIGS. 1 and 2, formed on a first, back side SB of a substrate 302 prior to the substrate 302 being attached to a circuit package (not shown). The bump interconnect 300 provides an electrically conductive path to transfer signals or power between circuit devices 304 on a second, front side SF of the semiconductor substrate 302 and circuits (not shown) external to the semiconductor substrate 302. The bump interconnects 300 include conductive pillars 306 with a solder 308 on a first end E1. The conductive pillars 306 each have a second end E2 with multiple surfaces 309 (“isolated end surfaces”) that provide a plurality of isolated contact areas 310 at which the second end E2 of the conductive pillar 306 contact a metal pad 311 to provide a low resistance electrical contact with reduced stress between the bump interconnects 300 and the metal pad 311. In this context, the term “contact” may include “direct contact” (e.g., without intervening layers) or “indirect contact” (e.g., with one or more intervening layers). Excessive stress where the conductive pillar 306 and the metal pad 311 are in contact can cause defects, such as separation of the conductive pillar 306 and the metal pad 311. Since the metal pad 311 electrically couples the bump interconnect 300 to the circuit devices 304, such separation can result in electrical disconnects or intermittent coupling. The conductive pillar 306 and the metal pad 311 are formed of conductive materials, such as copper or other metals or conductive materials, for example, which may be the same or different from each other.

The first, back side SB of the substrate 302 includes an insulating layer 312 on which the metal pad 311 is formed. The insulating layer 312 insulates the metal pad 311 from the substrate 302, but the metal pad 311 may be electrically coupled to the circuit devices 304 on the front side SF by metal traces and/or vias (not shown). In some examples, the substrate 302 may include metal traces, vias, and interconnects without having a circuit device 304 on the second side.

As discussed above with reference to the IC package 200 in FIG. 2, the bump interconnects 206 and the underfill 222 both expand when heated in a reflow process and may expand at different rates due to having different CTEs. Such differences in expansion rates can cause stresses (e.g., “contact stresses”) at the interface (e.g., the contact areas) of the bump interconnect 300 and the metal pad 311. To reduce such stresses occurring at the second end E2 of the conductive pillar 306, along a perimeter 314 of the second end E2, a passivation layer 316 is disposed between, in the Z-axis direction, the perimeter 314 and the metal pad 311.

The passivation layer 316 includes a hard passivation layer 318 and a polymer passivation layer 320, with the hard passivation layer 318 disposed between the polymer passivation layer 320 and the metal pad 311. The hard passivation layer 318 may comprise silicon oxide (SiO2) or silicon nitride (SiN), and the polymer passivation layer 320 may comprise any appropriate polymer, such as a polyimide material. As described below with reference to FIG. 3B, the hard passivation layer 318 is formed first on the metal pad 311, and the polymer passivation layer 320 is formed subsequently over the hard passivation layer 318.

In addition to forming the passivation layer 316 at the perimeter 314, the passivation layer 316 is also disposed in a pattern 322 across the second end E2 of the conductive pillar 306. The pattern 322 includes openings (“holes”) 324 that allow a conductive material 326 of the conductive pillar 306, which is formed or deposited on top of the passivation layer 316, to extend through the openings 324 and contact the metal pad 311. In this regard, the second end E2 is divided by the passivation layer 316 into the isolated end surfaces 309, each in contact with the metal pad 311 in isolated contact areas 310. For example, the conductive material 326 may be deposited or otherwise formed on the metal pad 311 after formation of the pattern 322 of the passivation layer 316. In such examples, the conductive material 326 extends through the openings 324 to contact the metal pad 311. The isolated end surfaces 309, and the isolated contact areas 310 may take the shape of the openings 324, which are determined by a mask (not shown, described below) in a fabrication process.

The magnitude of tensile stresses within the bump interconnect 300, in the isolated contact areas 310 where the conductive pillar 306 contacts the metal pad 311, is smaller than that of a single, larger contact in which the stress is more concentrated. In this regard, the plurality of isolated contact areas 310 is employed instead of a single larger end surface and contact area, as shown in a conventional bump interconnect described below, to distribute the stresses, which reduces stress magnitude in the bump interconnect 300. Since the isolated end surfaces 309 are all surfaces of the conductive pillar 306, the isolated contact areas 310 electrically couple, in parallel, the conductive pillar 306 and the metal pad 311. Therefore, the bump interconnect 300 may have at least a comparable (e.g., similar or the same) contact area, where the conductive pillar 306 and the metal pad 311 are in contact with each other, as a conventional bump interconnect with a single contact area that is greater in size than any of the isolated end surfaces 309. In this manner, the bump interconnect 300 reduces stress levels while maintaining or improving the electrical resistance at the interface between the conductive pillar 306 and the metal pad 311.

FIG. 3B is a cross-sectional end view 301B (e.g., from the direction of the metal pad 311) looking at the second end E2 of the bump interconnect 300, as shown in FIG. 3A. FIG. 3B shows the plurality of isolated contact areas 310 arranged in the pattern 322, coupling the conductive pillar 306 to the metal pad 311, as shown in FIG. 3A. The passivation layer 316 is disposed along the perimeter 314 of the second end E2 of the conductive pillar 306 between, in the Z-axis direction, the second end E2 and the metal pad 311. The isolated contact areas 310 correspond to the openings 324 in the passivation layer 316. The passivation layer 316 is disposed around the isolated end surfaces 309 and isolates, providing boundaries between the respective isolated end surfaces 309 in the isolated contact areas 310, separating them from each other. The passivation layer 316 may be disposed between the isolated end surfaces 309 in directions (X-axis and Y-axis) that are parallel to the isolated contact areas 310 on the metal pad 311.

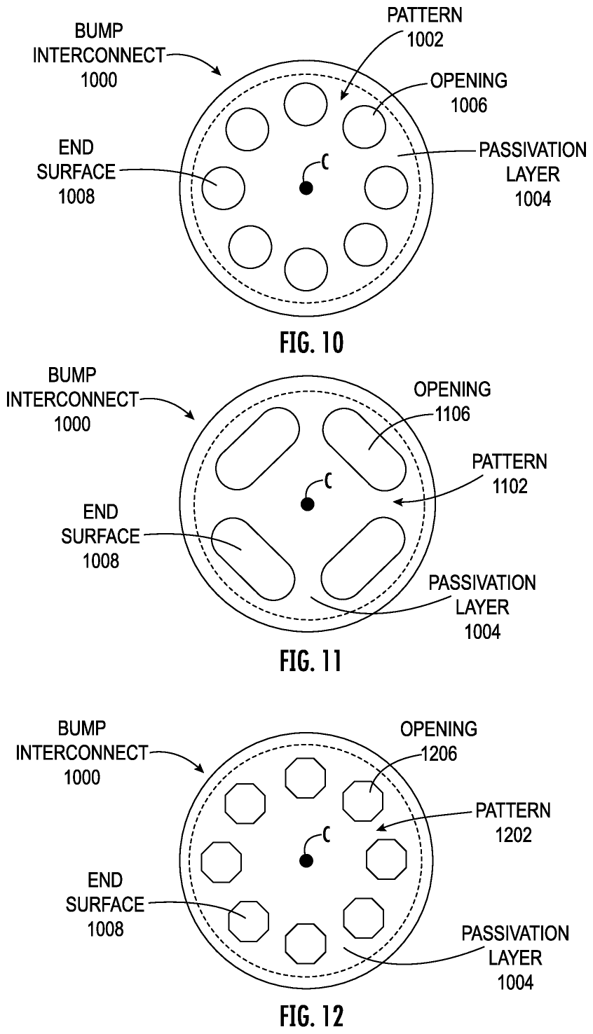

The pattern 322 in FIG. 3B, in which the openings 324 are round holes through the passivation layer 316, is just one example. Examples of other shapes of the openings 324 in the pattern 322 are shown in FIGS. 10-12. The openings 324 and the corresponding shapes of the isolated contact areas 310 may be circular, oblong, polygonal, linear, or other appropriate shapes. The pattern 322 includes at least two isolated end surfaces 309 to provide at least two isolated contact areas 310, at least four isolated contact areas 310, or at least ten isolated contact areas 310 depending on factors including a size of the cross-section 330 and shapes of the isolated contact areas 310. In FIG. 3B, the openings 324 form round isolated contact areas 310, but the shape is not limited in this regard and may be any shape in which an opening 324 in the mask is formed. The pattern 322 of the openings 324 may be symmetric or asymmetric and uniform or non-uniform. In some examples, the pattern 322 may include the passivation layer 316 disposed at a center point CE2 of the cross-section 330 of the second end E2. Stated differently, the passivation layer 316 may not have an opening 324 at the center CE2 of the cross-section 330 of the second end E2 of the conductive pillar 306.

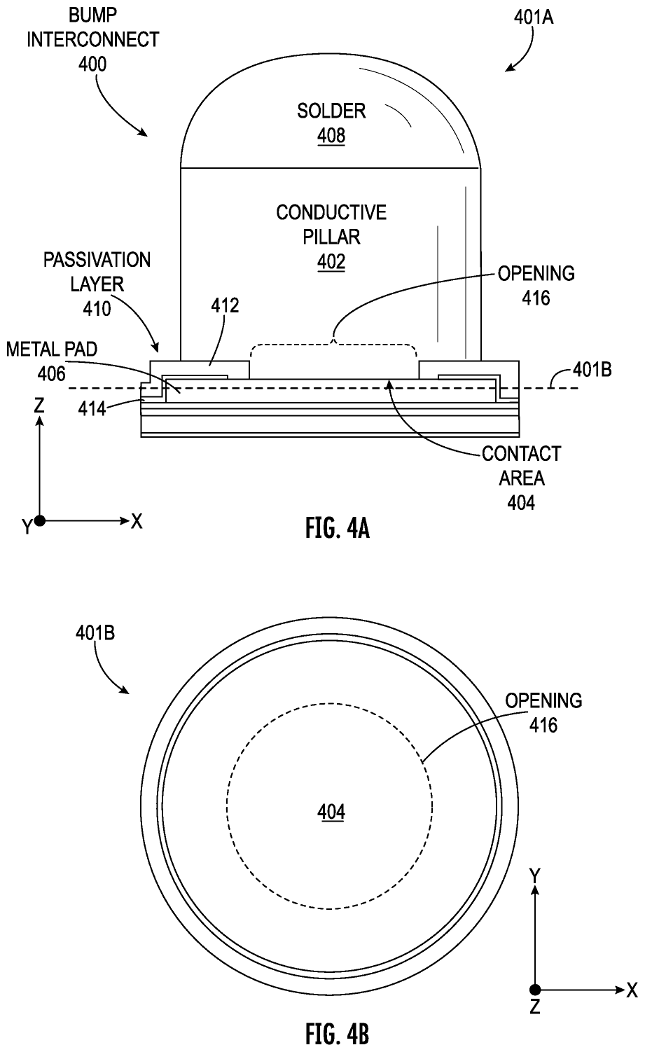

FIGS. 4A and 4B are a cross-sectional side view 401A and a cross-sectional bottom view 401B of a conventional bump interconnect 400 provided for comparison to FIGS. 3A and 3B. As shown, a conductive pillar 402 has a single continuous contact area 404 in contact with a metal pad 406. The bump interconnect 400 also includes a solder 408 and a passivation layer 410 that includes a polymer passivation layer 412 and a hard passivation layer 414. The contact area 404 is formed in a single opening 416 through the passivation layer 410. The opening 416 is formed in the hard passivation layer 414 and the polymer passivation layer 412.

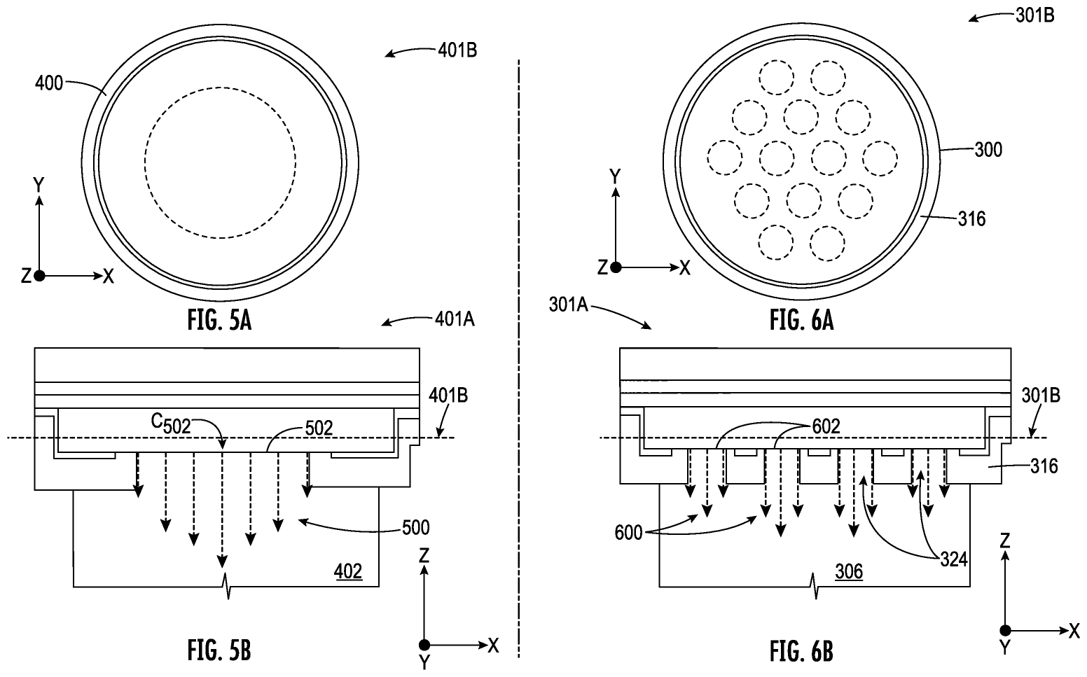

FIGS. 5A and 6A are a cross-sectional end view 401B of the conventional bump interconnect 400 and a cross-sectional end view 301B, respectively, of the exemplary bump interconnect 300 of FIGS. 4B and 3B. FIGS. 5B and 6B are inverted cross-sectional side views 401A and 301A of the conductive pillars 402 and 306 of the bump interconnects 300 and 400, respectively. FIGS. 5B and 6B also include respective stress vectors 500 and 600, illustrating stress magnitudes across the conductive pillars 402 and 306, where the magnitude corresponds to a length of the vectors across the contact area 502 in FIGS. 5A and 5B and the plurality of isolated contact areas 602 in FIGS. 6A and 6B. The contact areas 602 are portions of the conductive pillar 306 extending through the openings 324 in the passivation layer 316. As shown in FIG. 5B, a higher stress magnitude occurs in the larger continuous contact area 502, particularly in a center region C₅₀₂ where the stresses are in their highest concentration, which increases the possibility of stress-related defects. Therefore, ICs employing an array of bump interconnects corresponding to the bump interconnect 300 in FIGS. 3A, 3B, and 6A are less likely to have stress-related defects, which may affect transmission of signals and/or power.

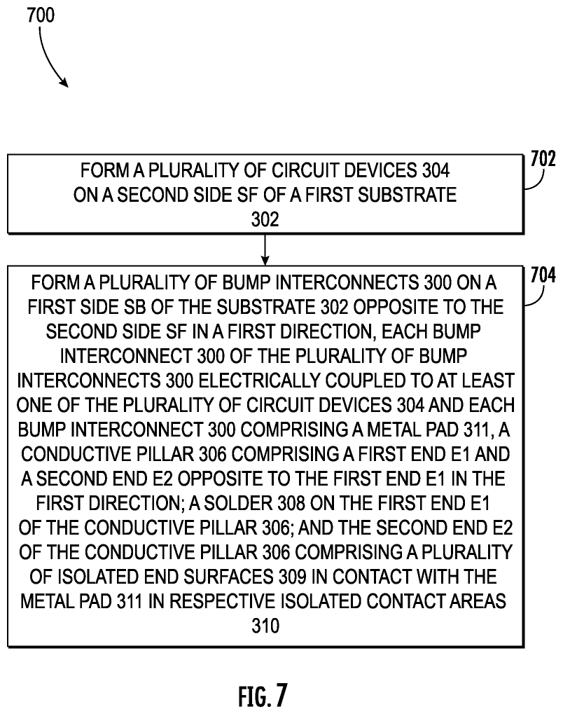

Fabrication processes can be employed to fabricate ICs having bump interconnects with a conductive pillar which includes multiple isolated end surfaces to provide isolated contact areas at which the conductive pillar contacts the metal pad with reduced stress, including but not limited to the bump interconnect 300 in FIGS. 3A, 3B, and the bump interconnect 300 in FIGS. 6A and 6B. In this regard, FIG. 7 is a flow chart illustrating an exemplary fabrication process 700 of fabricating an integrated circuit comprising bump interconnects, each with a conductive pillar that includes multiple isolated end surfaces to provide isolated contact areas at which the conductive pillar contacts the metal pad on the first substrate for reduced stress. The method includes forming a plurality of circuit devices 304 on a second side SF of a first substrate (block 702). The method further includes forming a plurality of bump interconnects 300 on a first side SB of the substrate 302 opposite to the second side in a first direction, each bump interconnect 300 of the plurality of bump interconnects 300 electrically coupled to at least one circuit device 304 among the plurality of circuit devices 304. Each bump interconnect 300 of the plurality of bump interconnects 300 comprises a metal pad 311, a conductive pillar 306 comprising a first end E1 and a second end E2 opposite to the first end E1 in the first direction, a solder 308 on the first end E1 of the conductive pillar 306, and the second end E2 of the conductive pillar 306 comprising a plurality of isolated end surfaces 309 in contact with the metal pad 311 in respective isolated contact areas 310 (block 704).

Other fabrication processes can also be employed to fabricate an integrated circuit comprising bump interconnects, each with a conductive pillar that includes multiple isolated end surfaces to provide isolated contact areas at which the conductive pillar contacts the metal pad on the first substrate for reduced stress, including but not limited to the bump interconnect 300 in FIGS. 3A, 3B, 6A, and 6B.

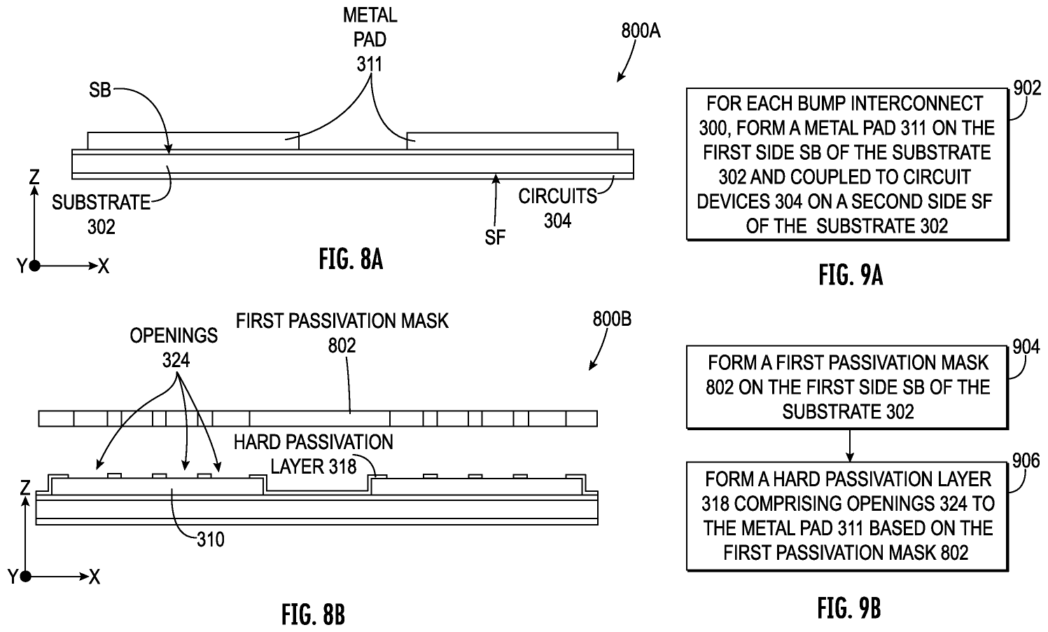

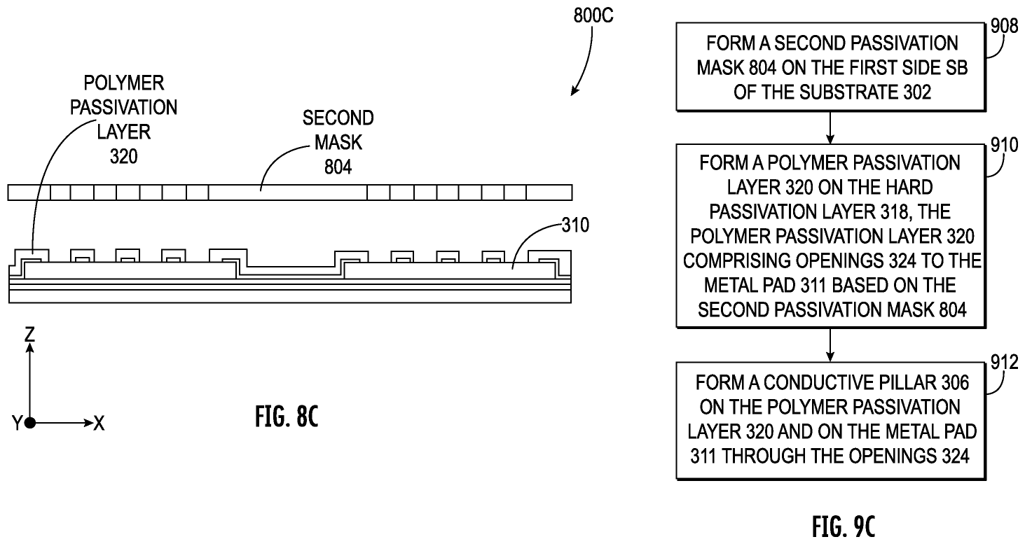

In this regard, FIGS. 8A-8C illustrate another exemplary fabrication process 800 of fabricating the bump interconnects in FIGS. 3A, 3B, 6A, and 6B, as shown in the stages of fabrication described in the flowchart in FIGS. 9A-9C. Features in FIGS. 8A-8C that are common to FIGS. 3A and 3B may be labeled alike and are not described again. FIG. 8A illustrates a first fabrication stage 800A described in FIG. 9A, including, for each of the bump interconnects 300, forming a metal pad 311 on the first side SB of the substrate 302 and coupled to circuit devices 304 on a second side SF of the substrate 302 (block 902). FIG. 8B illustrates a next fabrication stage 800B, described in FIG. 9B, wherein forming each of the plurality of bump interconnects further includes forming a first passivation mask 802 on the first side SB of the substrate 302 (block 904) and forming a hard passivation layer 318 comprising openings 324 to the metal pad 311 based on the first passivation mask 802 (block 906). In some examples, the hard passivation layer 318 is disposed on the metal pad 311 along a perimeter 314 for the conductive pillar 306. In some examples, the hard passivation layer 318 includes a plurality of openings 324 corresponding to the isolated contact areas 310 on the metal pad 311. FIG. 8C illustrates a next fabrication stage 800C described in FIG. 9C, including forming a second passivation mask 804 on the first side SB of the substrate 302 (block 908) and forming a polymer passivation layer 320 on the hard passivation layer 318, the polymer passivation layer 320 comprising openings 324 to the metal pad 311 based on the second passivation mask 804 (block 910). In some examples, the polymer passivation layer 320 is formed on the hard passivation layer 318 along the perimeter 314 of the conductive pillar 306 and around the openings 324 in the hard passivation layer 318. Forming the bump interconnect 300 further comprises forming a conductive pillar 306 on the polymer passivation layer 320 and on the metal pad 311 through the openings 324 (block 912).

FIGS. 10-12 are cross-sectional bottom views of examples of bump interconnects 1000, 1100, and 1200 formed by respective patterns 1002, 1102, and 1202 in passivation layers 1004, 1104, and 1204 of openings 1006, 1106, and 1206 that cause formation of surfaces (“isolated end surfaces”) 1008, 1108, and 1208 having particular shapes and separated or isolated from each other. The openings 1006 of the pattern 1002 cause the isolated end surfaces 1008 to be formed with round surface areas, like the isolated contact areas 310 in FIG. 3B. In contrast, the openings 1106 in the pattern 1102 create isolated end surfaces 1108 having oblong surface areas, and the openings 1206 in the pattern 1202 form octagonal surface areas in the isolated end surfaces 1208. The openings in the passivation layers are formed by masks, as described above, which can create openings having other shapes, including other polygons, for example. None of the patterns 1002, 1102, and 1202 have openings 1006, 1106, and 1206 at the centers of the second end surface E2 of the conductive pillars. In other words, the passivation layers 1004, 1104, and 1204 cover the centers of the second end surfaces E2.

The integrated circuits, including bump interconnects on a first substrate, wherein each bump interconnect includes a respective conductive pillar having multiple isolated end surfaces providing isolated contact areas at which the conductive pillar contacts a metal pad on a first substrate with reduced contact stresses according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

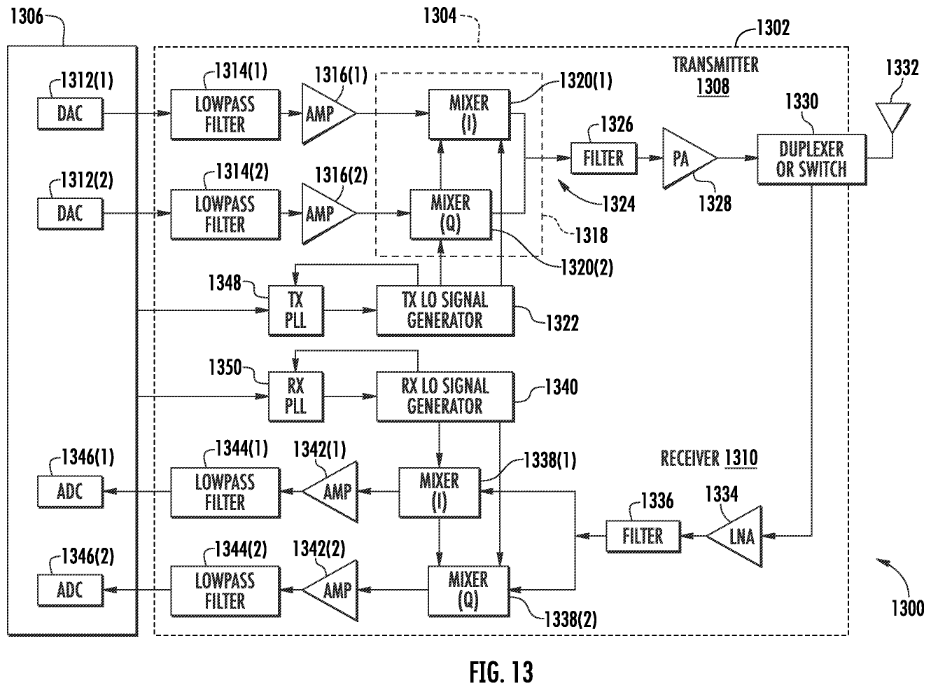

In this regard, FIG. 13 illustrates an exemplary wireless communication device 1300 that includes radio frequency (RF) components formed from one or more ICs 1302, wherein any of the ICs 1302 can include integrated circuits, including bump interconnects, in which an isolated end surface of a conductive pillar includes a plurality of isolated contact areas coupled to a metal pad to reduce stress between the conductive pillar and the metal pad without increasing resistance, as illustrated in FIGS. 3A and 3B and 10-12, and according to any aspects disclosed herein. The wireless communications device 1300 may include or be provided in any of the above-referenced devices as examples. As shown in FIG. 13, the wireless communications device 1300 includes a transceiver 1304 and a data processor 1306. The data processor 1306 may include a memory to store data and program codes. The transceiver 1304 includes a transmitter 1308 and a receiver 1310, which support bi-directional communications. In general, the wireless communications device 1300 may include any number of transmitters 1308 and/or receivers 1310 for any number of communication systems and frequency bands. All or a portion of the transceiver 1304 may be implemented on one or more analog ICs, RF ICs (RFICs), mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I, and Q transmit (TX) local oscillator (LO) signals from a TX LO signal generator 1322 through mixers 1320(1), 1320(2) to provide an upconverted signal 1324. A filter 1326 filters the upconverted signal 1324 to remove undesired signals caused by the frequency upconversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Downconversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency upconversion, while the RX LO signal generator 1340 generates the I and Q RX LO signals used for frequency downconversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

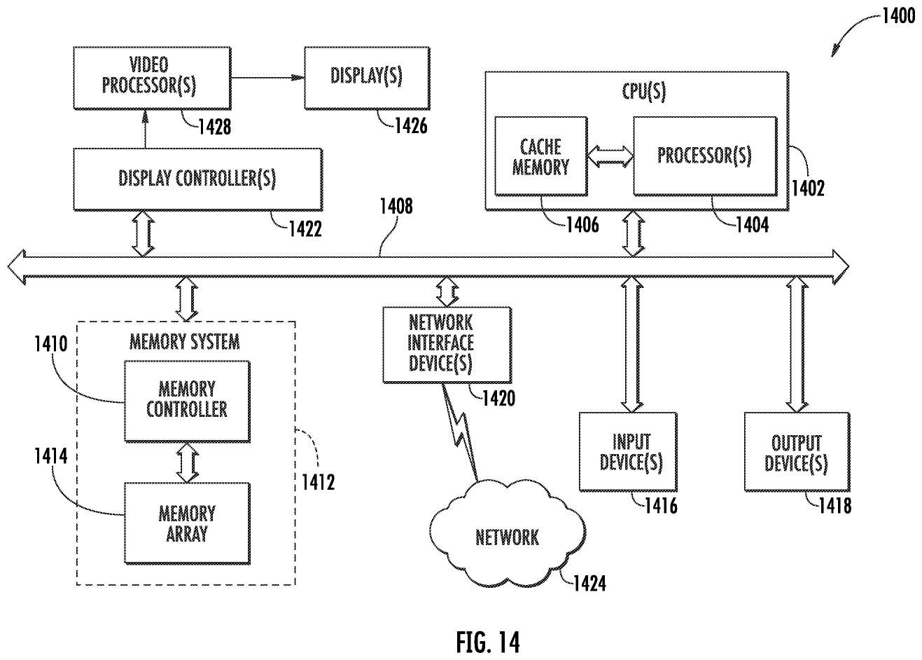

FIG. 14 illustrates an example of a processor-based system 1400 that can employ include IC(s), including bump interconnects on a first substrate, wherein each bump interconnect includes a respective conductive pillar having multiple isolated end surfaces providing isolated contact areas at which the conductive pillar contacts a metal pad on a first substrate with reduced contact stresses, as illustrated in FIGS. 3A 3B, 6A, 6B, and 10-12. In this example, the processor-based system 1400 includes one or more central processor units (CPUs) 1402, which may also be referred to as CPUs or processor cores, each including one or more processors 1404. The CPU(s) 1402 may have cache memory 1406 coupled to the processor(s) 1404 for rapid access to temporarily stored data. The CPU(s) 1402 is coupled to a system bus 1408 and can intercouple master and slave devices included in the processor-based system 1400. As is well known, the CPU(s) 1402 communicates with these other devices by exchanging address, control, and data information over the system bus 1408. For example, the CPU(s) 1402 can communicate bus transaction requests to a memory controller 1410 as an example of a slave device. Although not illustrated in FIG. 14, multiple system buses 1408 could be provided; wherein each system bus 1408 constitutes a different fabric.

Other master and slave devices can be connected to the system bus 1408. As illustrated in FIG. 14, these devices can include a memory system 1412 that includes the memory controller 1410 and one or more memory arrays 1414, one or more input devices 1416, one or more output devices 1418, one or more network interface devices 1420, and one or more display controllers 1422, as examples. The input device(s) 1416 can include any type of input device, including, but not limited to, input keys, switches, voice processors, etc. The output device(s) 1418 can include any type of output device, including, but not limited to, audio, video, other visual indicators, etc. The network interface device(s) 1420 can be any device configured to allow an exchange of data to and from a network 1424. The network 1424 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1420 can be configured to support any type of communications protocol desired.

The CPU(s) 1402 may also be configured to access the display controller(s) 1422 over the system bus 1408 to control information sent to one or more displays 1426. The display controller(s) 1422 sends information to the display(s) 1426 to be displayed via one or more video processors 1428, which process the information to be displayed into a format suitable for the display(s) 1426. The display(s) 1426 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:
1. An integrated circuit (IC) chip comprising:
   a plurality of bump interconnects on a first side of a first substrate; and
   a plurality of circuit devices on a second side of the first substrate opposite the first side in a first direction;
   wherein:
      the plurality of bump interconnects electrically coupled to at least one circuit device among the plurality of circuit devices; and
      each bump interconnect of the plurality of bump interconnects comprises:
         a metal pad;
         a conductive pillar comprising a first end and a second end opposite the first end in the first direction;
         a solder on the first end of the conductive pillar; and
         the second end of the conductive pillar comprising a plurality of surfaces in contact with the metal pad in respective contact areas.
2. The IC of clause 1, each bump interconnect further comprising:
   a passivation layer disposed around and isolating each of the plurality of surfaces of the second end of the conductive pillar.
3. The IC of clause 1 or clause 2, each bump interconnect further comprising:
   a passivation layer disposed between, in the first direction, a perimeter of the second end of the conductive pillar and the metal pad.
4. The IC of any of clause 1 to clause 3, wherein:
   the passivation layer comprises openings corresponding to each of the plurality of surfaces of the second end of the conductive pillar; and
   each of the plurality of surfaces extends through the openings to contact the metal pad in the contact areas.
5. The IC of any of clause 1 to clause 4, the passivation layer further comprising:
   a polymer passivation layer; and
   a hard passivation layer disposed between, in the first direction, the polymer passivation layer and the metal pad.
6. The IC of any of clause 1 to clause 5, wherein:
   the plurality of surfaces comprises a uniform pattern of end surfaces of the second end of the conductive pillar.
7. The IC of any of clause 1 to clause 6, wherein:
   each of the plurality of surfaces comprises a circular surface area.
8. The IC of any of clause 1 to clause 6, wherein:
   each of the plurality of surfaces comprises an oblong surface area.
9. The IC of any of clause 1 to clause 6, wherein:
   each of the plurality of surfaces comprises a polygonal surface area.
10. The IC of any of clause 1 to clause 9, wherein:
   the plurality of surfaces comprises at least four (4) surfaces.
11. The IC of any of clause 1 to clause 9, wherein:
   the plurality of surfaces comprises at least ten (10) surfaces.
12. The IC of any of clause 1 to clause 11, wherein:
   the passivation layer is disposed at a center of a cross-section of the second end of the conductive pillar.
13. The IC of any of clause 1 to clause 12 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
14. A method of fabricating an integrated circuit (IC) comprising:
   forming a plurality of circuit devices on a second side of a first substrate; and
   forming a plurality of bump interconnects on a first side of the first substrate opposite in a first direction to the second side of the substrate and electrically coupled to first circuit devices among the plurality of circuit devices, each bump interconnect of the plurality of bump interconnects comprising:
      a metal pad;
      a conductive pillar comprising a first end and a second end opposite the first end in the first direction;
      a solder on the first end of the conductive pillar; and
      the second end of the conductive pillar comprising a plurality of surfaces in contact with the metal pad in respective contact areas.
15. The method of clause 14, wherein forming the plurality of bump interconnects comprises, for each bump interconnect of the plurality of bump interconnects, forming the metal pad on the first side of the first substrate and coupled to a circuit device of the plurality of circuit devices on the second side of the substrate.
16. The method of clause 14 or clause 15, wherein forming each of the plurality of bump interconnects further comprises:
   forming a first passivation mask on the first side of the first substrate; and
   forming a hard passivation layer comprising openings to the metal pad based on the first passivation mask.
17. The method of any of clause 14 to clause 16, wherein forming each of the plurality of bump interconnects further comprises:
   forming a second passivation mask on the first side of the first substrate; and
   forming a polymer passivation layer on the hard passivation layer, the polymer passivation layer comprising openings to the metal pad based on the second passivation mask.
18. The method of any of clause 14 to clause 17, wherein forming each of the plurality of bump interconnects further comprises forming the conductive pillar on the polymer passivation layer, comprising forming surfaces of an end of the conductive pillar in contact with the metal pad through the openings in the polymer passivation layer.
19. An integrated circuit (IC) package, comprising:
   a first substrate;
   a plurality of bump interconnects on a first side of the first substrate, each bump interconnect comprising:
      a metal pad;
      a conductive pillar comprising a first end and a second end opposite to the first end in a first direction;
      a solder on the first end of the conductive pillar; and
      a plurality of surfaces at the second end of the conductive pillar in contact with the metal pad in a plurality of respective contact areas;
   a second substrate comprising a plurality of contact pads, each coupled to the solder of a corresponding one of the plurality of bump interconnects;
   a plurality of circuit devices on a second side of the first substrate opposite to the first end in a first direction; and
   the plurality of bump interconnects electrically coupled to at least one of the plurality of circuit devices and to the second substrate.
20. The IC package of clause 19, each bump interconnect further comprising:
   a passivation layer disposed between, in the first direction, a perimeter of the second end of the conductive pillar and the metal pad; and
   a passivation layer disposed around and isolating each of the plurality of surfaces of the second end of the conductive pillar.
21. The IC package of clause 19 or clause 20, wherein, in each bump interconnect:
   the passivation layer comprises openings corresponding to each of the plurality of contact areas; and
   the second end of the conductive pillar extends through the openings to form the plurality of contact areas of the conductive pillar in contact with the metal pad.
22. The IC package of any of clause 19 to clause 21, wherein:
   the plurality of contact areas comprises a uniform pattern of contact areas of the second end of the conductive pillar.
23. The IC package of any of clause 19 to clause 22, wherein:
   each of the plurality of contact areas comprises a circular contact area.
24. The IC package of any of clause 19 to clause 23, wherein:
   the plurality of contact areas comprises at least four (4) contact areas.
25. The IC package of any of clause 19 to clause 23, wherein:
   the plurality of contact areas comprises at least ten (10) contact areas.

What is claimed is:

1. An integrated circuit (IC) chip comprising:
a plurality of bump interconnects on a first side of a first substrate; and
a plurality of circuit devices on a second side of the first substrate opposite the first side in a first direction;
wherein:
the plurality of bump interconnects electrically coupled to at least one circuit device among the plurality of circuit devices; and
each bump interconnect of the plurality of bump interconnects comprises:
a metal pad;
a conductive pillar comprising a first end and a second end opposite the first end in the first direction;
a solder on the first end of the conductive pillar; and
the second end of the conductive pillar comprising a plurality of surfaces in contact with the metal pad in respective contact areas.

2. The IC of claim 1, each bump interconnect further comprising:
a passivation layer disposed around and isolating each of the plurality of surfaces of the second end of the conductive pillar.

3. The IC of claim 1, each bump interconnect further comprising:
a passivation layer disposed between, in the first direction, a perimeter of the second end of the conductive pillar and the metal pad.

4. The IC of claim 2, wherein:
the passivation layer comprises openings corresponding to each of the plurality of surfaces of the second end of the conductive pillar; and
each of the plurality of surfaces extends through the openings to contact the metal pad in the contact areas.

5. The IC of claim 2, the passivation layer further comprising:
a polymer passivation layer; and
a hard passivation layer disposed between, in the first direction, the polymer passivation layer and the metal pad.

6. The IC of claim 1, wherein:
the plurality of surfaces comprises a uniform pattern of end surfaces of the second end of the conductive pillar.

7. The IC of claim 1, wherein:
each of the plurality of surfaces comprises a circular surface area.

8. The IC of claim 1, wherein:
each of the plurality of surfaces comprises an oblong surface area.

9. The IC of claim 1, wherein:
each of the plurality of surfaces comprises a polygonal surface area.

10. The IC of claim 1, wherein:
the plurality of surfaces comprises at least four (4) surfaces.

11. The IC of claim 1, wherein:
the plurality of surfaces comprises at least ten (10) surfaces.

12. The IC of claim 2, wherein:
the passivation layer is disposed at a center of a cross-section of the second end of the conductive pillar.

13. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

14. A method of fabricating an integrated circuit (IC) comprising:
forming a plurality of circuit devices on a second side of a first substrate; and
forming a plurality of bump interconnects on a first side of the first substrate opposite in a first direction to the second side of the substrate and electrically coupled to first circuit devices among the plurality of circuit devices, each bump interconnect of the plurality of bump interconnects comprising:
a metal pad;
a conductive pillar comprising a first end and a second end opposite the first end in the first direction;
a solder on the first end of the conductive pillar; and
the second end of the conductive pillar comprising a plurality of surfaces in contact with the metal pad in respective contact areas.

15. The method of claim 14, wherein forming the plurality of bump interconnects comprises, for each bump interconnect of the plurality of bump interconnects, forming the metal pad on the first side of the first substrate and coupled to a circuit device of the plurality of circuit devices on the second side of the substrate.

16. The method of claim 15, wherein forming each of the plurality of bump interconnects further comprises:
forming a first passivation mask on the first side of the first substrate; and
forming a hard passivation layer comprising openings to the metal pad based on the first passivation mask.

17. The method of claim 16, wherein forming each of the plurality of bump interconnects further comprises:
forming a second passivation mask on the first side of the first substrate; and
forming a polymer passivation layer on the hard passivation layer, the polymer passivation layer comprising openings to the metal pad based on the second passivation mask.

18. The method of claim 17, wherein forming each of the plurality of bump interconnects further comprises forming the conductive pillar on the polymer passivation layer, comprising forming surfaces of an end of the conductive pillar in contact with the metal pad through the openings in the polymer passivation layer.

19. An integrated circuit (IC) package, comprising:
a first substrate;
a plurality of bump interconnects on a first side of the first substrate, each bump interconnect comprising:
a metal pad;
a conductive pillar comprising a first end and a second end opposite to the first end in a first direction;
a solder on the first end of the conductive pillar; and
a plurality of surfaces at the second end of the conductive pillar in contact with the metal pad in a plurality of respective contact areas;
a second substrate comprising a plurality of contact pads, each coupled to the solder of a corresponding one of the plurality of bump interconnects;
a plurality of circuit devices on a second side of the first substrate opposite to the first end in a first direction; and
the plurality of bump interconnects electrically coupled to at least one of the plurality of circuit devices and to the second substrate.

20. The IC package of claim 19, each bump interconnect further comprising:
a passivation layer disposed between, in the first direction, a perimeter of the second end of the conductive pillar and the metal pad; and
a passivation layer disposed around and isolating each of the plurality of surfaces of the second end of the conductive pillar.

21. The IC package of claim 19, wherein, in each bump interconnect:
the passivation layer comprises openings corresponding to each of the plurality of contact areas; and
the second end of the conductive pillar extends through the openings to form the plurality of contact areas of the conductive pillar in contact with the metal pad.

22. The IC package of claim 19, wherein:
the plurality of contact areas comprises a uniform pattern of contact areas of the second end of the conductive pillar.

23. The IC package of claim 19, wherein:
each of the plurality of contact areas comprises a circular contact area.

24. The IC package of claim 19, wherein:
the plurality of contact areas comprises at least four (4) contact areas.

25. The IC package of claim 19, wherein:
the plurality of contact areas comprises at least ten (10) contact areas.
